(19) United States
(12) Patent Application Publication
(10) Pub. No.: US 2009/0003882 A1
(43) Pub. Date: Jan. 1, 2009

(54) Light Emitting Element, Light Emitting Element Array, Method Of Manufacturing Light Emitting Element And Light Emitting Element Array, And Exposing Apparatus

(75) Inventors: Tetsurou Nakamura, Hyogo (JP); Yuuji Toyomura, Fukuoka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/571,032

(22) PCT Filed: Apr. 20, 2006
(86) PCT No.: PCT/JP2006/308289

§ 371 Date: Dec. 20, 2006

(30) Foreign Application Priority Data
May 9, 2005 (JP) 2005-135551

(51) Int. Cl. G03G 15/04; H01J 1/63; B05D 5/12

(52) U.S. Cl. 399/220; 313/504; 427/66

(57) ABSTRACT

An insulator (12), which is provided between a lower electrode (11) by patterning a substrate and a counter electrode (15), defines a light emitting area by covering on ends of the lower electrode (11). The light emitting area (13) has a shape of which edges in a first direction of the substrate are defined by at least the insulator (12) and other edges in a second direction on the substrate different from the first direction are defined by one of the lower electrode (11) and the counter electrode (15). A plurality of the light emitting elements is placed independent electrically in the second direction on the substrate, whereby a light emitting array and an exposure apparatus is formed.

### TECHNICAL FIELD

The present invention relates to light emitting element, light emitting element array on which minute light emitting elements are placed in line and the like, method of manufacturing thereof, and exposing apparatus with the light emitting element array, which are applied to an electrophotographic printer.

### BACKGROUND ART

The electrophotographic printer exposes an electrified photoconductor according to image data, and forms an electrostatic latent image corresponding to the image data on the photoconductor. After the latent image is developed with toner, the developed toner image on the photoconductor is transformed on a recording paper, and then the image is obtained by heat-fixing the transformed image thereon. A well-known type of the exposing apparatus to be used to such electrophotographic printer is configured to form the electrostatic latent image by enabling the light beam from a light source having laser diode to scan the photoconductor surface via a rotative polyhedron mirror such as polygon mirror. As the same type of the exposing apparatus, there is another well-known system which includes a light emitting element array formed by placing the light emitting diode (LED) or light emitting elements using the organic electroluminescence (EL) material in line, and controls the lighting (on-off control) of each light emitting element respectively to form the electrostatic latent image on the photoconductor.

Generally, the exposing apparatus having the light emitting element array formed by LED or the light emitting elements using the organic EL material is configured to light selectively each light emitting element at a position very close to the photoconductor surface, and irradiates the light on the photoconductor. Therefore, the printer with this exposing apparatus, as compared with a laser printer using laser beam, has no moving part like the polygon mirror, so that the printer has a high reliability. The printer does not require both optical systems to conduct light from the laser diode to the photo conductor and large optical spaces to form light paths. Therefore, it is possible to make a more compact printer

In case of the exposing apparatus applying the organic EL material to the light emitting elements, it is possible to fabricate a driving circuit consisting of switching devices made of thin film transistor (TFT) with the organic EL light emitting element in one piece on a substrate like glass. Therefore, as compared with a LED head applying LED to the light emitting element, the exposing apparatus has a simplified configuration and a simple manufacturing process, and has a possibility to realize more compact and low-cost product.

The organic EL light emitting element has a configuration wherein the organic EL material is deposited between a lower electrode and a counter electrode. The organic EL material emits light by applying voltage between the lower electrode and the counter electrode. In this case, a region on which the lower electrode and the counter electrode are superposed is a light emitting area of the organic EL light emitting element. In the process for manufacturing the organic EL light emitting element, the counter electrode is deposited after the lower electrode and the organic EL material film is formed on the substrate. The method of depositing the counter electrode is the vapor deposition method in general. In the vapor deposition method, since a metal material gets into under a shadow-mask placed close and above the organic EL material film, it is hard to form the counter electrode with high accuracy. And a minute light emitting area cannot be formed with high precision. Therefore, in order to form the minute light emitting area with high accuracy, an edge of the light emitting area is defined by a dielectric film pattern.

In the organic EL light emitting element array used to a display, as disclosed in Patent document 1, it is well-known that the light emitting element array has a dielectric film which is used to an electrical isolation, and each light emitting element section (light emitting areas) is formed by its opening. In Patent document 2, the dielectric film with openings formed by the patterning is superposed on a part of the lower electrode that is the electrode of the light emitting element, and thereby the shape of the light emitting element section (the lighting emitting area) is formed more accurately. FIG. 1 in Patent document 2 shows that an opening 10 of a dielectric film 3 formed by the patterning becomes a light emitting element section (a light emitting area), and the accuracy of form is improved.

Patent document 1: U.S. Pat. No. 4,670,690

Patent document 2: Japan Patent No. 2,734,464

### DISCLOSURE OF THE INVENTION

### Problem to be Solved by the Invention

However, a static image processed by the printer requires fine and accurate picture elements more than that of dynamic image processed by the display. When the organic EL light emitting elements are used to the exposing apparatus of the printer, the light emitting element section (the light emitting area, or a picture element for a formed bitmap image) requires the high accuracy of shape and the high uniformity of the light emitting surface as compared with that of the display. In case of the organic EL light emitting element array having the conventional configuration described above, the accuracy of form cannot always be secured enough on the opening of the dielectric film that becomes the light emitting element section.

The light emitting element array used to the exposing apparatus of the printer requires being higher density than that for the display. In recent yeas, the printer, the digital copying machine, and the multi-function printer (MFP) get higher picture quality and higher resolution than ever, in which the light emitting element having the light emitting area to be a picture element should be placed linearly in a direction with pitches corresponding to the high resolution which is from several-fold to over twenty-fold display resolution. For instance, in the exposing apparatus wherein the printing resolution is 600 dpi (dot per inch), the light emitting elements must be placed with 42.3 μm pitches. In the exposing apparatus having the 2400 dpi resolution, the pitches placing the light emitting elements are 10 μm approximately.

It is inevitable that the size of light emitting area (width) at this case must be less than a pitch of the light emitting element. Also, in case that the size of light emitting area is configured to be as large as possible within this range in order to obtain larger light volume, a space between neighboring light emitting elements must be a few μm. However, in the conventional configuration described in Patent document 1, it is difficult to form the above-mentioned size of opening on the dielectric film. In the configuration described in Patent document 2, the alignment accuracy between the opening of the dielectric film and its corresponding lower electrode at every light emitting element section is not enough in the dielectric film patterning. Accordingly, the space between the neighboring light emitting elements must be over 10 μm, so that the width (size) of light emitting element becomes small.

In the conventional organic EL light emitting element array having the light emitting area formed by the opening of the dielectric film, the patterning accuracy of the opening on the dielectric film, the alignment accuracy between the opening and the lower electrode, and the space between the neighboring openings cannot comply with the resolution required by the current printer, and hereupon it is difficult to carry out the printer with high resolution. In addition, there is a subject that it is impossible to form enough size of the light emitting element section, and obtain a sufficient exposure performance of the exposing apparatus.

The present invention is suggested in order to settle the above-mentioned subject. The invention has objects to provide an exposing apparatus having a light emitting element array wherein the light emitting elements with a light emitting area to be a picture element are placed with short pitches in order to obtain the high resolution, and the light emitting area (size) is formed as large as possible to obtain the high exposure performance; the light emitting element; the light emitting element array; and the method of manufacturing thereof.

### Means for Solving Problem

To achieve the above object, the light emitting element in the present invention comprises a drive electrode on which voltage for the light emitting is applied; a dielectric film for covering ends of the drive electrode, and a light emitting area defined by the drive electrode and the dielectric film.

The light emitting element in the invention having a light emitting area including a lower electrode, an organic multilayer film with a light emitting layer and a counter electrode on a substrate, comprises a dielectric film that is formed by patterning on the substrate and between the lower electrode and the counter electrode, and covers ends of the lower electrode to prevent the light emitting from a covered area. The light emitting area has a shape of which edges are defined by the dielectric film and other edges are defined by the lower electrode formed by patterning on the substrate or the counter electrode formed by patterning on the substrate.

The light emitting element in the invention having a light emitting area including a lower electrode, an organic multilayer film with a light emitting layer and a counter electrode on a substrate, comprises a dielectric film that is formed by patterning on the substrate between the lower electrode and the counter electrode, and covers ends of the lower electrode to prevent the light emitting from a covered area. The light emitting area has a shape of which edges in a specific direction (a first direction) on the substrate are defined by at least the dielectric film and other edges in a second direction different from the first direction are defined by at least one of the lower electrode formed by patterning on the substrate and the counter electrode by patterning on the substrate.

The exposing apparatus in the invention includes a light emitting element, and it may be configured by the light emitting element comprising a drive electrode on which voltage for the light emitting is applied; a dielectric film for covering ends of the drive electrode. The light emitting area is defined by the drive electrode and the dielectric film.

The exposing apparatus in the present invention includes plural light emitting elements, and it may be configured so that each light emitting element comprising a light emitting area having a lower electrode on a substrate, an organic multilayer film with a light emitting layer, and a counter electrode on the substrate; and a dielectric film formed by patterning on the substrate and placed between the lower electrode and the counter electrode, and covering ends of the lower electrode to prevent the light emitting from a covering area, wherein the light emitting area has an shape of which edges in a first direction on the substrate are defined by at least the dielectric film and other edges in a second direction different from the first direction is defined by at least one of the lower electrode formed by patterning on the substrate and the counter electrode by patterning on the substrate, and the plural light emitting elements are placed in line in the second direction so that the element is electrically isolated each other.

A method of manufacturing a light emitting element having a light emitting area including a lower electrode on a substrate, an organic multilayer film with a light emitting layer and a counter electrode on a substrate, or a method of manufacturing a light emitting element array of which light emitting elements are placed in line, the method comprises the steps of: forming the lower electrode on the substrate; forming the dielectric film on the substrate with the lower electrode by patterning; forming the organic multilayer film with the light emitting layer on the substrate with the lower electrode and the dielectric film; and forming the counter electrode on the substrate on which the lower electrode, the dielectric film and the organic multilayer film are formed, wherein in at least one step of the step of forming the lower electrode and the step of forming the counter electrode, the lower electrode is formed by patterning on the substrate or the counter electrode is formed by patterning on the substrate, and the light emitting area has a shape of which edges are defined by the dielectric film, and other edges are defined by the lower electrode or the counter electrode.

### EFFECT OF THE INVENTION

The light emitting element in the invention has the light emitting area that is defined by the drive electrode and the dielectric film, or the shape of the light emitting area that is defined by the shape of the drive electrode and the shape of the dielectric film. Hereupon, depending on the required accuracy in a part of edge of the light emitting area, the part of edge is defined by either the drive electrode or the dielectric film with the required accuracy, so that it is possible to ensure the required accuracy. In addition, when the plural light emitting elements are placed in line and the pitch of the light emitting element is short, it is possible to reduce the space between the neighboring light emitting elements, and make the light emitting area larger. Therefore, the exposure can be performed with high picture quality and high resolution.

In the light emitting element in the invention, the light emitting element has a shape of which edges are defined by the dielectric film which is an electrical isolation, and other edges are defined by the lower electrode formed by patterning on the substrate and the counter electrode by patterning on the substrate. Accordingly, depending on the required accuracy in a part of edge of the light emitting area, the part of the edge is defined by any one of the lower electrode, the counter electrode or the dielectric film with the required accuracy so that it is possible to ensure the required accuracy. In addition, when the plural light emitting elements are placed in line and the pitch of the light emitting element is short, it is possible to reduce the space between the neighboring light emitting elements, and make the light emitting area larger. Therefore, there is an effect that the exposure can be performed with high picture quality and high resolution.

### BRIEF DESCRIPTION OF THE DRAWING

FIG. 1 is a sectional view of a light emitting element array of an exposing apparatus in connection with a first embodiment of the present invention.

FIG. 2 is a top view of a light emitting element array of an exposing apparatus in connection with a first embodiment of the present invention.

FIG. 3 is a top view of a light emitting element array of an exposing apparatus in connection with a second embodiment of the present invention.

FIG. 4 is a schematic diagram for illustrating a method of forming an organic multilayer film with a light emitting layer of the present invention.

### DESCRIPTION OF THE INVENTION

The following description discusses about embodiments of the present invention according to attached drawings.

### First Embodiment

This embodiment is concerned with a light emitting element array for an exposing apparatus of the present invention.

The exposing apparatus is a means of the electrophotographic apparatus for forming an electrostatic latent image on a photoconductor. The exposing apparatus in this embodiment is provided with the light emitting element array wherein a plurality of minute light emitting elements related to this invention are placed in line or in lines (the direction of this line is called a main scanning direction). The electrostatic latent image can be formed on the photoconductor by controlling lighting and extinguishing of the light emitting element at specific intervals based on an image data.

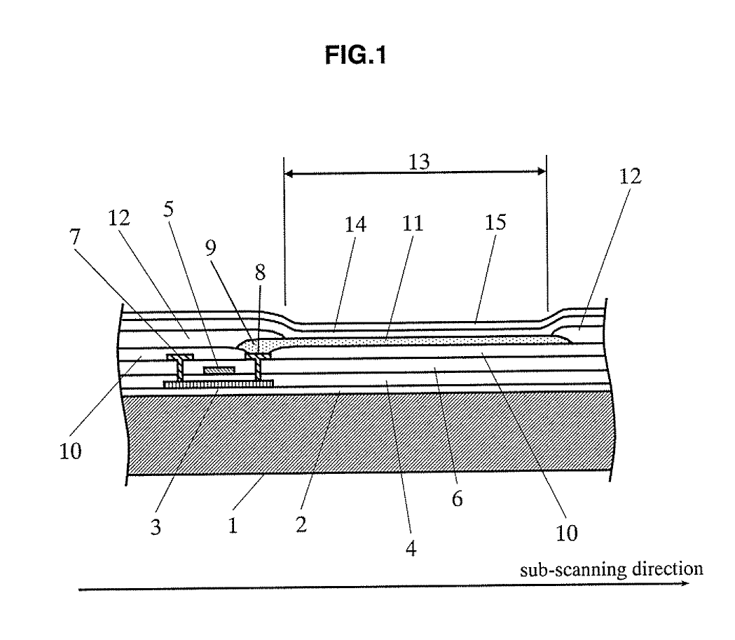

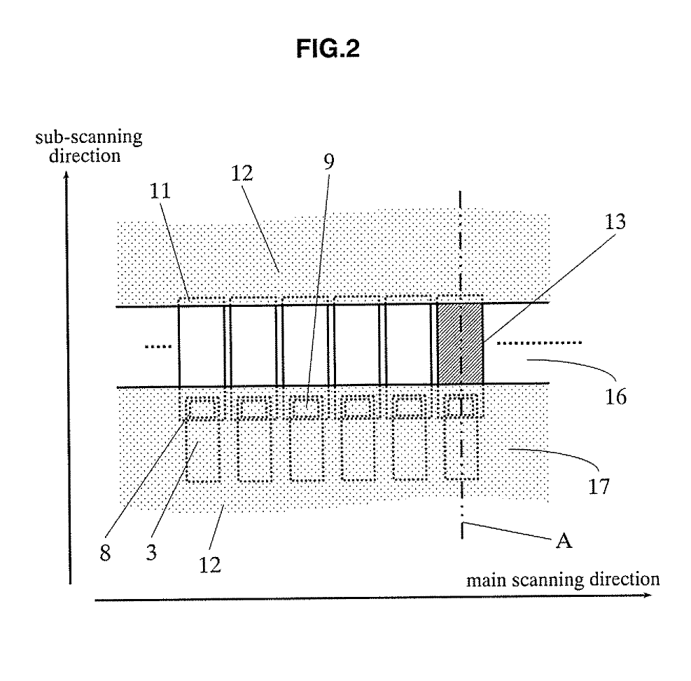

FIG. 1 and FIG. 2 show the light emitting element array in connection with the present invention. FIG. 2 is a top view thereof. FIG. 1 is a sectional view on line A (the direction perpendicular to the main scanning direction, and called a sub-scanning direction) shown in FIG. 2.

In FIG. 1, a glass substrate 1 is made of borosilicate glass, for example. A base coating layer 2 is configured by depositing SiNx and SiO₂, for example.

On the base coating layer 2, TFT 3 made of polycrystalline silicon (polysilicon) is formed. The TFT 3 made of polycrystalline silicon, as of now, can drive a load by 5 MHz of driving frequencies, and also can be fabricated with a relative fine design rule in degree of from 1.5 μm to 4.5 μm, so that it is possible to make the size of the substrate small.

A gate insulating layer 4 is made of SiO₂, for example, and insulates between a gate electrode 5 made of metal such as Mo and TFT 3 with keeping a specific distance therefrom.

An intermediate layer 6 is formed by depositing SiO2 and SiNx. The intermediate layer 6 coats the gate electrode 5, and supports a source electrode 7 and a drain electrode 8 made of metal such as Al and the like and formed along with the surface of the intermediate layer 6.

The source electrode 7 and the drain electrode 8 are connected to the TFT 3 via a contact hole 9 provided to the intermediate layer 6 and the gate insulating layer 4. In case that a specific potential is applied on the gate electrode 5 keeping a specific potential difference between the source electrode 7 and the drain electrode 8, the TFT 3 works as a switching transistor.

A TFT surface layer 10, which is made of SiNx, coats the source electrode 7 completely and has the contact hole 9 at a part of the drain electrode 8.

A lower electrode (hole injection electrode) 11 made of ITO (Indium Tin Oxide) is formed on the TFT surface layer 10 by the sputtering method, in this embodiment. The lower electrode 11 is connected to the drain electrode 8 via the contact hole 9.

By forming the TFT 3 and the others on the glass substrate 1 in the above-mentioned structure, a TFT substrate is formed.

In the next step, a dielectric film 12 that is an electrical isolation for the TFT substrate is formed on the TFT surface layer 10 and above the surface on which the TFT 3 is formed, which is made of SiNx with 300 nm of film thickness. The dielectric film 12 covers ends of the lower electrode 11, and thereby an after-mentioned light emitting area 13 is defined in size, shape, and position. In this embodiment, the dielectric film 12 covers both ends of the lower electrode 11 on a sub-scanning direction and a position on which the contact hole 9 is formed, completely, as shown in the figure. Therefore, the organic EL layer on this covered area does not emit light, and the size and shape of the light emitting area 13 in the sub-scanning direction are defined. Additionally, even if the film thickness of the organic EL layer changes due to a step of the contact hole 9, it is possible to eliminates the unevenness of the luminescence of the light emitting area 13.

On the dielectric film 12 thus formed, an organic multilayer film 14 including a light emitting layer (the organic EL layer) is formed by a spin coat method or a vapor deposition method.

A counter electrode (cathode) 15 is formed by depositing a metal, such as Al and the like, with the vapor deposition method.

An arrangement of the light emitting elements (the light emitting area 13) included in the light emitting element array of this embodiment is discussed in details as follows.

FIG. 2 shows a state that the organic multilayer film 14 including the light emitting layer and the counter electrode 15 are removed, and the lower electrode is visible. The TFT 3 and the drain electrode 8 are illustrated by a broken line, which means that the TFT 3 and the drain electrode 8 are covered by the lower electrode 11 or the TFT surface layer 10.

In FIG. 2, the lower electrode 11 is placed in the main scanning direction with 600 dpi pitches. Specifically, the pitch of the lower electrode 11 is 42.3 μm. In the 42.3 μm pitch of the lower electrode, a space between neighboring lower electrodes 11 is 5 μm.

The lower electrode 11 is formed by the photo-etching in which a pattern corresponding to the lower electrode 11 is formed on the TFT surface layer 10 using by exposing through a photomask having a pattern corresponding to the lower electrode 11. At this time, the pattern formed by exposing is configured that a pitch of the pattern corresponding to the lower electrodes in the main scanning direction is 600 dpi and a space between the neighboring patterns corresponding to lower electrodes is 3 μm. Those values are determined based on that, in the positive type process to be remove the exposed portion, an edge of the remaining pattern after the removal process (the lower electrode 11, in this case) shrinks about 1 μm. In result, the space between the neighboring lower electrodes 11 becomes 5 μm. Considering the shrinkage caused by the process for the exposed pattern, it makes it possible to obtain a desired size of lower electrode 11.

According to the above process, the lower electrodes placed in line with 600 dpi pitches in the main scanning direction and the 5 μm space between the neighboring lower electrodes form a group of lower electrodes as shown in FIG. 2. On the lower electrode group, the organic multilayer film 14 including the light emitting layer and the counter electrode 15 are formed as mentioned above. Therefore, a light emitting element group 16 in which the light emitting areas 13 that is independent for every lower electrode are placed with 600 dpi pitches in the main scanning direction and the 5 μm space between the light emitting areas is obtained. In the method, the electrode is formed by the patterning so as to be processable in the minute size with accuracy, in result, even in the organic EL light emitting system that plural light emitting areas are placed in line, each light emitting area placed in the line direction can have a minute size and shape.

On the other hand, the dielectric film 12, which was formed on the TFT surface layer 10 and the lower electrode 11, covers the ends in the sub-scanning direction of the lower electrode 11 for the light emitting element group 16, as described above. Hereupon, each light emitting area 13 is defined in size and shape in the sub-scanning direction.

In the printer using the exposing apparatus with the light emitting element array, the printing resolution is determined as follows: the resolution of the main scanning direction on which the light emitting elements are placed in line is determined substantially based only on the pitch for placing the light emitting element on the light emitting element array, while the resolution of the sub-scanning direction, which is perpendicular to the main scanning direction and indicates a direction of movement of the photoconductor (a direction of rotation of the photoconductive drum), is determined based on both the size of the light emitting element and the movement of the photoconductor (the rotation of the photosensitive drum).

In the exposing apparatus of this embodiment, the resolution of the sub-scanning direction, which depends on the size of the light emitting element and the movement of the photoconductor (the rotation of the photosensitive drum), is defined by the edges of the light emitting area in the sub-scanning direction covered by the dielectric film 12 that is the electrical isolation. Meanwhile, the resolution of the main scanning direction, which depends on the pitch for placing the light emitting element and the size of the light emitting element, is defined by the electrode formed by the patterning so as to be processable in a minute size and accurate. Therefore, the exposing apparatus in this embodiment can carry out the printing with high resolution and high accuracy.

The every lower electrode 11 is connected to the drain electrode 8 formed by Al and the like on the undersurface of the lower electrode 11 with a one-to-one correspondence between the lower electrode and the drain electrode. The drain electrode 8 is substantially connected to the TFT 3 that is not visible by the TFT surface layer 10. The drain electrode 8 is extended to a specific length from the TFT 3 to the sub-scanning direction, of which end is connected to the lower electrode 11 via the contact hole 9, as shown in FIG. 1. The same configuration is provided in the main scanning direction, then the TFT 3 forms a TFT group 17 in the main scanning direction.

The light emitting element group 16 and the TFT group 17 are placed in the sub-scanning direction on the glass substrate surface so as to absolutely separate from each other. The lower electrode 11 included in the light emitting element group 16 is connected to the TFT 3 included in the TFT group 17 via the metal drain electrode 8. In this way, the area of the light emitting element group 16 is separated completely from the area of the TFT group 17. It is possible to form the TFT 3 that is long in the sub-scanning direction.

Accordingly, the above-mentioned simplified configuration eliminates the overlap of the light emitting area 13 and the TFT 3, and also absolutely separates the area of the light emitting element group 16 from the area of the TFT group 17. It is possible to ensure the area disposing the TFT 3 in the sub-scanning direction sufficiently.

As described above, the size and shape of the light emitting area 13 in the sub-scanning direction is defined by the dielectric film 12, and as for the main scanning direction on which a plurality of the light emitting areas are placed in line, the size and shape of the light emitting area 13 is defined by the accurate lower electrode 11 formed by patterning. By such configuration, the exposing apparatus can be configured that the space between picture elements is on the order of 5 μm. Therefore, each light emitting area 13 can be formed in size and position in proper and with high accuracy. The uniformity of the exposing performance can be realized by controlling the unevenness of emitted light volume. While ensuring the necessary light emitting areas, it is possible to realize the exposing head with high resolution with ease, of which resolution is 1200 dpi or 2400 dpi in the main scanning direction.

Besides, in case that a thin film transistor constituting an active matrix drive circuit becomes large in order to control the emitted light volume with high accuracy, or in case that a large current drive is required to increase the light volume, that is, the transistor size gets large, it is possible to ensure the disposed space of the TFT 3 in the sub-scanning direction.

The glass substrate 1 may use a quartz and the like as the substrate in case that heat generated by the light emitting element and the drive circuit is to be released quickly.

This embodiment uses the polycrystalline silicon as a material of the TFT 3, however, an amorphous silicon could be used. Regarding the design rule and the driving frequency, the amorphous silicon is at a disadvantage as compared with the polycrystalline silicon, but there is a cost advantage because its manufacturing process is inexpensive.

As lower electrode 11, IZO (Indium Zinc Oxide), ZnO, SnO₂, In₂O₃, and the like can be used instead of ITO used in this embodiment, but it is preferable to use ITO or IZO. Also, the lower electrode 11 can be formed by the vapor deposition method, but the lower electrode 11 can be preferably formed by the sputtering method.

As dielectric film 12, a transparent organic material like resin can be used. It is general that, when the dielectric film is formed with the organic material, the film becomes thick in several μm. Owing to the trouble of a contact angle with the organic multilayer film 14 including the light emitting layer that is formed on the dielectric film 12, a failure of the light emitting will occur. Therefore, the dielectric film 12 is desired to use an inorganic material allowed to form the layer more thinly, and to make the step around the light emitting area small. As another inorganic material of the dielectric film 12, it is possible to use SiO₂ and the like.

In this embodiment, the organic multilayer film 14 with the light emitting layer is formed on the dielectric film 12 that is the electrical isolation, and the dielectric film 12 is a layer sandwiched between the lower electrode 11 and the organic multilayer film 14. However, the electrical isolation is not necessary to be sandwiched between the organic multilayer film 14 and the lower electrode 11. For instance, the organic multilayer film 14 with the light emitting layer may not be formed on the electrical isolation by means of the inkjet method which will be described in a third embodiment.

When forming the organic multilayer film 14 with the light emitting layer, a hole injection layer using the metal oxide and the like may be formed between the organic multilayer film 14 and the lower electrode 11.

The material of the organic EL may be a low-molecular material, or a high-molecular material.

When the counter electrode 15 is formed, an electron injection layer may be formed between the organic multilayer film 14 with the light emitting layer and the counter electrode 15. The electron injection layer is desired to have a structure, for example, wherein a metallic element such as K, Li, Na, Mg, La, Ce, Ca, Sr, Ba, Al, Ag, Ln, Sna, Zn, and Zr, or an alloy of two or three of those elements to improve the stability is deposited sequentially in order of Ca, Al, for example from a side near to the organic multilayer film 14 with the light emitting layer.

Regarding the light emitting area 13 in this embodiment, the size and shape in the sub-scanning direction is defined by the dielectric film 12, and the size and shape in the main scanning direction is defined by the lower electrode 11, however, it is not limited to this combination. If the accuracy of form required by the light emitting area 13 can be realized by an arbitrary combination of the dielectric film 12, the lower electrode 11, the counter electrode 15, and the other components, the same effect can be obtained. An edge of the light emitting area defined by one component is not always perpendicular to another edge of the light emitting area defined by another component, and the angle may be arbitrary. The component to define the shape of the light emitting area 13 is not necessary to specify for every edge of the light emitting area. The component to define the shape of the light emitting area 13 may vary for every light emitting element.

In addition, the shape of the light emitting area 13 is not necessary to be a two dimensional shape (a plan form). In case of a three dimensional convexo-concave shape, the accuracy of form can be carried out by any combination of the dielectric film 12, the lower electrode 11, the counter electrode 15 and the other components, to form and define the light emitting area 13.

### Second Embodiment

In the first embodiment, the light emitting area 13 is a rectangle, wherein the edge in the main scanning direction is defined to a straight line by the lower electrode 11 and the other edge in the sub-scanning direction is defined to a straight line by the dielectric film 12. This embodiment relates to the light emitting element array having the light emitting elements, of which the edge in the main scanning direction is nonlinear by the lower electrode and the other edge in the sub-scanning direction is nonlinear by the dielectric film which is electrical isolation, so that the shape of the light emitting area includes the nonlinear edges.

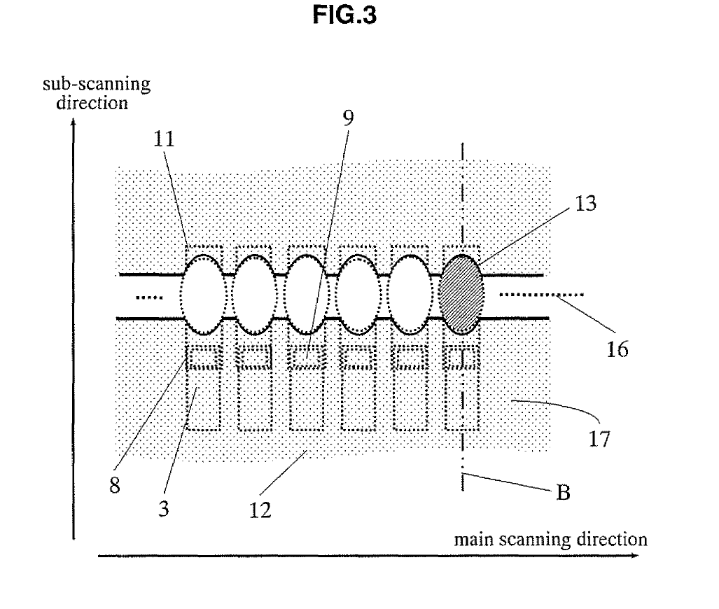

FIG. 3 is a top view of the light emitting element array of the exposing apparatus in this embodiment. A cross section on a line B shown in FIG. 3 (this direction is called the sub-scanning direction, while the main scanning direction is perpendicular to the sub-scanning direction and it is a line on which the light emitting elements are placed) is the same as the first embodiment (FIG. 1). The arrangement of the light emitting elements (the light emitting areas 13) of the light emitting element array in this embodiment is discussed hereinafter with reference to FIG. 1 and FIG. 3.

Each light emitting element of the light emitting element array in the invention has the light emitting area of which shape is defined by a shape of the lower electrode 11. Also, the light is not emitted from the organic multilayer film 14 with the light emitting layer in an area on which the dielectric film 12 is placed. Accordingly, the shape of the light emitting area 13 is defined by the shape of the lower electrode 11 and the shape of the dielectric film 12.

In FIG. 1 and FIG. 3, the dielectric film 12 is made of SiNx, and 30 nm thickness, for example. It is formed by the photo-etching. The lower electrode 11 is also formed by the photo-etching.

The dielectric film 12 and the lower electrode 11 are formed by the photo-etching, so that they can be formed in various patters (shapes) depending on the photomask pattern (shape). In this embodiment, the lower electrode 11 is formed in a nonlinear shape including an arc and the dielectric film 12 is formed in a nonlinear shape including an arc, whereby the shape of the light emitting area 13 is defined.

The dielectric film 12 and the lower electrode 11 are formed by the patterning as above, and are combined to form the light emitting area 13. The formed light emitting area 13 has a very high flexible size and shape as compared with that formed by the dielectric film 12 only. For example, the light emitting area 13 can be formed in not only an oval but also a circle. Therefore, it is possible to realize freely an optimum shape of the light emitting area, in order to uniform the light volume distribution after the light passes through the optical system such as a lens array. By matching the shape and the size of the light emitting area 13 to the light spot shape and the property of the electrophotography, the exposing performance of the exposing apparatus can be improved.

The dielectric film 12 covers the area above the contact hole 9 completely in the same way as the first embodiment, so that the organic multilayer film 14 with the light emitting layer in this area does not emit light. Accordingly, as mentioned in the first embodiment, the unevenness of the light volume of the light emitting area 13 caused by the step of the contact hole 9 can be eliminated in this embodiment, too.

Like the first embodiment, the area of the light emitting element group 16 is completely separated from the area of the TFT group 17, and the TFT 3 can be formed and extended long in the sub-scanning direction.

As described above, the light emitting element in this invention can be configured so that, in the simple manner that the lower electrode 11 and the dielectric film 12 are formed by the patterning, the overlap of the valid light emitting area and the TFT 3 can be eliminate, and it is possible to separate the area of the light emitting element group 16 from the area of the TFT group 17 completely. In addition, by defining the shape of the light emitting area 13 freely while controlling the unevenness of the light volume, it is possible to provide the high-performance exposing apparatus having the light-spot shape corresponding to the property of the electrophotography.

The light emitting area in the embodiment has the nonlinear edges on first and second directions, however, the light emitting area having only the nonlinear edges on one direction may be formed easily. The angle of the directions of two edges is not limited to a right angle, and it may be an arbitrary angle. The component to define the shape is not specified for every direction, and the component may be different for every light emitting element and the like.

### Third Embodiment

This embodiment describes the process for manufacturing the light emitting array described in the first and second embodiments, and specifically describes a method of forming the organic multilayer film with the light emitting layer of the light emitting element array. The light emitting element array to be manufactured in this embodiment is the light emitting element array described in the first and second embodiment, thus the structure of the light emitting element array is shown in FIG. 1 and in FIG. 2 or FIG. 3. In this embodiment, FIG. 1 to FIG. 3 are referred.

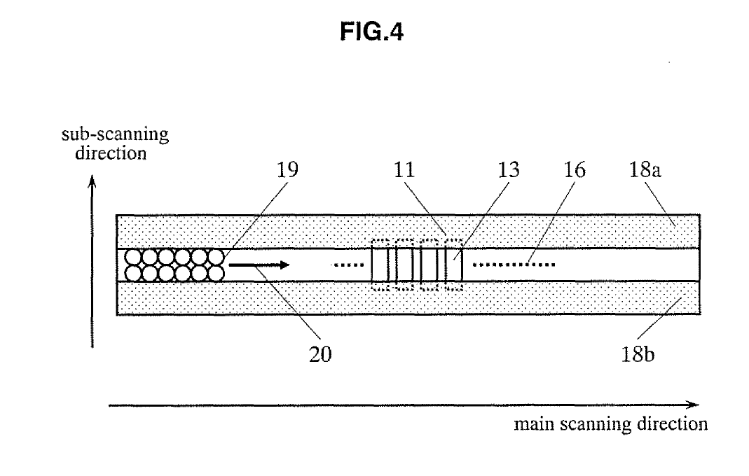

FIG. 4 is a schematic diagram for explaining the method of forming the organic multilayer film with the light emitting layer. FIG. 4 is a top view of a semi-finished product, which is to be the light emitting element array described in the first and second embodiment, before the organic multilayer film is formed. In FIG. 4, the shape of the after-mentioned lower electrode 11 is illustrated by the shape of the light emitting element array in the first embodiment.

The semi-finished light emitting element array shown in FIG. 4 is in a state that the lower electrode 11 and the insulator 18 for electrical isolation have been formed on the glass substrate 1 (in a state that processes for forming the components has been carried out) as mentioned in the first or second embodiments (FIG. 1), namely, it is in a state before the organic multilayer film 14 with the light emitting layer shown in FIG. 1 is formed. In this embodiment, the semi-finished light emitting element array under such conditions is called a light emitting element array simply.

In FIG. 4, the lower electrode 11 is formed by the patterning using the photo-etching as described in the first or second embodiments. An insulator 18 has two parts (18a and 18b) that are formed long in the main scanning direction as shown in FIG. 4, and respective insulators cover each ends of the lower electrode 11. That it to say, the two insulators 18a and 18b have a structure formed long in the main scanning direction respectively, and each lower electrode 11 is arranged and exposing its center portion in a stripe zone formed by the two insulators 18a and lab. The light emitting area 13 is an area which is enabled to emit light under energized condition after the organic multilayer film 14 with the light emitting layer is formed by the method described later and the counter electrode 15 in FIG. 1 has been formed.

In this embodiment, the organic multilayer film 14 with the light emitting layer is formed by ejecting a liquid to be the organic multilayer film 14 (the liquid containing a constituent material for the organic multilayer film 14) onto the light emitting array. An ejection nozzle 19 for ejecting the liquid is placed above a position to form the organic multilayer film 14. The position of a plurality of the ejection nozzles 19 is expressed schematically in FIG. 4.

The respective ejection nozzles 19 in this embodiment are supported by an inkjet head (not shown in the drawing) mounted so as to be slidable along the main scanning direction. In the instance shown in FIG. 4, twelve ejection nozzles 19 are arranged such as six nozzles in the main scanning direction and two nozzles in the sub-scanning direction, which are supported by the inkjet head. Here, two ejection nozzles 19 placed in the sub-scanning direction are able to eject the liquid onto the whole width of the stripe zone between the two insulators (18a and 18b).

Under a condition that the twelve ejection nozzles is formed as a group in such way, the organic multilayer film with the light emitting layer is formed as follows. The light emitting element array is in the state that the lower electrode 11 and the insulator 18 have been formed on the glass plate 1. This light emitting element array is placed below the inkjet head. At this time, the inkjet head has a position and a direction same as the group of the ejection nozzles 19, as shown in FIG. 4. That is to say, the nozzle group is at an end of the stripe zone between the two insulators 18a and 18b, and it is placed so that a longitudinal direction of the nozzle group (a line of six ejection nozzles 19) is the same as that of the longitudinal direction of the stripe zone (the main scanning direction).

In the next step, a specific amount of the liquid to be the organic multilayer film 14 is ejected onto the light emitting element array from the twelve ejection nozzles 19 of the inkjet head. According to this ejecting, the liquid is applied onto the whole width of the stripe zone between the two insulators 18a and 18b with thinly and uniformly, for a specific length (in FIG. 4, the length of the six ejection nozzles 19) in the longitudinal direction (the main scanning direction).

After this, the inkjet head is shifted toward an arrow 20 in the main scanning direction for the specific length. At this position, the inkjet head ejects the liquid in the same way as mentioned above. Then, the repeat of the shifting and ejecting of the inkjet head is done all over the light emitting element group 16 in the same way. Accordingly, all the liquid ejected by the inkjet head forms a film, and the organic multilayer film with the light emitting layer can be formed. The number of the ejecting onto a specific position may be one, or more than one. The specific amount of the liquid is ejected onto one position in plural steps. The liquid ejecting may be performed by the repeat of the moving of the inkjet head on the same line.

In this embodiment, as described above, the organic multilayer film is formed by ejecting the liquid such as the inkjet method, namely, applying the liquid thinly on all the light emitting areas moving the outlets of the plural ejection nozzles along the line of the light emitting elements. Therefore, even if the light emitting element array has many areas to be covered with the liquid, it is possible to form the organic multilayer film with ease. In addition, since the method in this method has an advantage that the organic multilayer film is not formed on the area not to form the organic multilayer film thereon, it is possible to reduce the consumption of the organic EL materials and saves the cost. It is also possible to reduce the different step caused by forming the lower electrode, the insulator, and the organic multilayer film on the substrate. In result, it is possible to improve the shape accuracy of a pattern such as the counter electrode to be formed in the subsequent process, and to increase the reliability on the pattern such as the counter electrode.

The inkjet head to eject the liquid may be moved to both directions on the main scanning direction (two-path: both ways of the reciprocating motion). According to such configuration, it is possible to apply the liquid in a short time on the specific section to be covered with the liquid.

The inkjet head in this embodiment is configured that the two ejection nozzles are placed in the sub-scanning direction so as to correspond to the width of the stripe zone between the two insulators 18a and 18b, however, the number of the ejection nozzles to be placed in the sub-canning direction may be one. In addition, the inkjet head may support only one ejection nozzle placed in the main scanning direction. In this case, the inkjet head is desired to be mounted so as to be slidable in the sub-scanning direction, too. Thereby, by ejecting the liquid from the inkjet head while moving the inkjet head to both the main scanning direction and the sub-scanning direction repeatedly, it is possible to eject the liquid onto the entire light emitting element group 16.

If it is necessary to improve a position accuracy of ejected liquid for the section to be covered with the liquid, the inkjet head may eject the liquid in one way of the main scanning direction (one path: one of the back and forth ways of the reciprocating motion). According to such configuration, it is possible to reduce a position error of the ejected liquid for every ejected position in the sub-scanning direction.

The process of forming the organic multilayer film may be performed by a set of the liquid ejectings from a group of the ejection nozzles placed in line having the same length as the line of the light emitting elements. That is to say, the inkjet head may be configured to be long enough to have the ejection nozzles corresponding to the whole length of the light emitting element group 16. In this case, the organic multilayer film can be formed by applying the liquid thinly without shifting the outlets of the plural ejection nozzles.

Then, in the process of forming the organic multilayer film, the inkjet head having above configuration forms the film by a set of the liquid ejectings which apply the liquid thinly from the nozzle group having a line of the plural ejection nozzles corresponding to the length of the light emitting element group without moving the outlets of the plural ejection nozzles. Therefore, even if the light emitting element array has a large section to form the organic multilayer film thereon, it is possible to provide the same effect as stated previously. Moreover, according to this configuration, it is possible to perform the liquid applying in a very short time, and reduce the manufacturing cost more than ever.

In the above instance, the inkjet head is configuration to be slidable, however, the same effect can be obtained by a fixed inkjet head and a slidable substrate. The above description is based on that the liquid to be ejected is one kind, but, when plural layers are formed depending on the film structure of the organic multilayer film, respective liquids containing a constituent material for each layer may be ejected onto the substrate sequentially.

As the material of the insulator, hydrophilic materials may be used. The insulator made of the hydrophilic material does not repel the organic multilayer film in a position surrounding the section to be the light emitting area, and the insulator is compatible with the organic multilayer film, so that the edges of the light emitting area can be formed accurate shape defined by the insulator formed by the patterning. Moreover, since the thickness of the organic multilayer film can be formed uniformly especially at the boundary between the organic multilayer film and the insulator, it is possible to make the light volume distribution and the light emitting angle distribution uniform. As the hydrophilic materials, anion, cation, and nonion can be used.

The preferred embodiments of the invention are the light emitting element, the light emitting element array, the exposing apparatus, the method of manufacturing the light emitting element, and the method of manufacturing the light emitting element array.

In accordance with an aspect of the present invention, there is provided with the light emitting element comprising a drive electrode on which voltage for the light emitting is applied, a insulator for covering ends of the drive electrode, and a light emitting area defined by the drive electrode and the insulator. In this configuration, depending on the required accuracy in a part of edge of the light emitting area, the part of the edge is defined by either the drive electrode or the dielectric film with the required accuracy, so that it is possible to ensure the required accuracy.

In the light emitting element, the shape of the light emitting area may be defined by a shape of the drive electrode and a shape of the insulator. In this configuration, it is possible to obtain the same effect as mentioned above.

In accordance with another aspect of the present invention, there is provided with the light emitting element array having plural light emitting elements placed in line, the light emitting element as mentioned above, wherein the light emitting area has a shape of which edges in the line direction are defined by the shape of the drive electrode and other edges in the other direction are defined by the shape of the insulator.

In such configuration, even if the plural light emitting elements are placed in line on the light emitting element array with a short pitch, the space between neighboring light emitting areas can be shorter, and the light emitting area can be obtained larger. Therefore, it is possible to realize the exposure with high picture quality and high resolution.

In accordance with another aspect of the present invention, there is provided with a light emitting element having a light emitting area including a lower electrode, an organic multilayer film with a light emitting layer and a counter electrode on a substrate, comprising a insulator formed by patterning on the substrate and placed between the lower electrode and the counter electrode, and covering ends of the lower electrode to prevent the light emitting from a covering area, wherein the light emitting area has a shape of which edges are defined by the insulator, and other parts are defined by the lower electrode formed by the patterning on the substrate or the counter electrode formed by the patterning on the substrate.

In such configuration, the light emitting area has a shape of which edges are formed by the electrical isolation and the other edges are formed by the lower electrode formed by the patterning or the counter electrode by the patterning. In this configuration, depending on the required accuracy in a part of edge of the light emitting area, the part of the edge is defined by any one of the lower electrode, the counter electrode or the dielectric film with the required accuracy, so that it is possible to ensure the required accuracy. Moreover, even if the plural light emitting elements are placed in line on the light emitting element array with a short pitch, the space between neighboring light emitting areas can be shorter, and the light emitting area can be obtained larger. Therefore, it is possible to realize the exposure with high picture quality and high resolution.

In accordance with still another aspect of the present invention, there is provided with a light emitting element having a light emitting area including a lower electrode, an organic multilayer film with a light emitting layer and a counter electrode on a substrate, comprising a insulator formed by patterning on the substrate and placed between the lower electrode and the counter electrode, and covering ends of the lower electrode to prevent the light emitting from a covering area, wherein the light emitting area has a shape of which edges in a first direction (a specific direction) on the substrate are defined by at least a insulator and other edges in a second direction different from the first direction on a substrate are defined by at least one of the lower electrode formed by patterning on a substrate and the counter electrode formed by patterning on a substrate.

In the above configuration, the light emitting area has a shape of which edges in the specific direction on the substrate are defined by the lower electrode and the other edges in the second direction different from the specific direction are defined by the lower electrode formed by the patterning or the counter electrode by the patterning. In this configuration, depending on the required accuracy in an edge of the light emitting area in a specific direction, the edge is defined by any one of the lower electrode, the counter electrode or the dielectric film with the required accuracy, so that it is possible to ensure the required accuracy. Moreover, even if the plural light emitting elements are placed in line on the light emitting element array with a short pitch, the space between neighboring light emitting areas can be shorter, and the light emitting area can be obtained larger. Therefore, it is possible to realize the exposure with high picture quality and high resolution.

In the light emitting element, the second direction may be approximately perpendicular to the first direction.

Accordingly, since the second direction is approximately perpendicular to the first direction, the both directions do not require the accuracy each other. For instance, it may be configured so that, if the specific direction has a higher accuracy, the other direction has a low accuracy.

In the above light emitting element, the organic multilayer film may be formed only on a gap between the neighboring insulators in the first direction. In this case, since the organic multilayer film is not formed on an unnecessary section, it is possible to reduce the necessary amount of the organic material and the cost. It is also possible to control the unevenness of the surface on the substrate on which the lower electrode, the insulator and the organic multilayer film are formed. It is possible to improve the reliability when the counter electrode is formed.

In the light emitting elements in the above aspects, both the edges of the light emitting area defined by the insulator and the edges defined by the lower electrode or the counter electrode may be a straight line. According to such configuration, in case of the specific resolution, the shape of the light emitting area is a rectangle surrounded by the straight lines. Therefore, the size (area) of the light emitting area becomes the biggest, from which a large light volume can be obtained. It is possible to reduce the luminance, and extend the life of the light emitting element.

In the light emitting elements of the above aspects, the edges of the light emitting area defined by the insulator and the edges defined by the lower electrode or the counter electrode may include a nonlinear part. In this case, the shape of the light emitting area can be optimized by forming in a shape including a circle or an ellipse based on the rectangle surrounded by straight lines, depending on a lens to be used and the exposing conditions.

In the above light emitting elements in the above aspects, the insulator may be formed by inorganic material, such as SiNx, SiO₂, and the like. In result, it is possible to ensure the uniformity of the thickness of the light emitting layer, the unevenness of the light emitted from the light emitting area can be controlled, and the life of the light emitting element can be extended. By means of this light emitting element, it is possible to ensure the high picture quality, the high resolution, and the high reliability of the printer.

In the light emitting elements in the above aspects, the thickness of the insulator may range from 100 nm to 3000 nm. According to such configuration, the light emitting element can be optimized in order to ensure the insulating properties and obtain the uniformity of the film thickness of the light emitting area.

In the light emitting elements in the above aspects, the organic multilayer film may be configured so as not to be formed on a whole area of the insulator. In this case, since the organic multilayer film is not formed on an unnecessary section, it is possible to reduce the necessary amount of the organic material and the cost. It is also possible to control the unevenness of the surface on the substrate on which the lower electrode, the insulator and the organic multilayer film are formed. It is possible to improve the reliability when the counter electrode is formed.

In the light emitting elements in the above aspects, the insulator may be made of a hydrophilic material. In this configuration, the insulator formed by the hydrophilic material does not repel the organic multilayer film in a position surrounding the section to be the light emitting area, and the insulator is compatible with the organic multilayer film, so that the edges of the light emitting area can be formed accurately by the insulator formed by patterning. Since the thickness of the organic multilayer film can be formed uniformly especially at the boundary between the organic multilayer film and the insulator, it is possible to make the light volume distribution and the light angle distribution uniform.

In accordance with still another aspect of the present invention, there is provided with an exposing apparatus including light emitting elements, each light emitting element comprising a drive electrode on which voltage for the right emitting is applied, a insulator for covering ends of the drive electrode, and a light emitting area defined by the drive electrode and the insulator.

In this configuration, since the edges of the light emitting area are defined by the drive electrode or the insulator. Therefore, depending on the required accuracy in a part of edge of the light emitting area, the part of the edge is defined by either the drive electrode or the dielectric film with the required accuracy, so that it is possible to ensure the required accuracy. Even if the plural light emitting elements are placed in line on the light emitting element array with a short pitch, the space between neighboring light emitting areas can be shorter, and the light emitting area can be obtained larger. Therefore, it is possible to realize the exposure with high picture quality and high resolution.

In this exposing apparatus, the shape of the light emitting area may be defined by a shape of the drive electrode and a shape of the insulator. In this configuration, it is possible to obtain the same effect as mentioned above.

In the exposing apparatus of which light emitting elements are placed in line, the light emitting area may have a shape of which edges in the line direction are defined by the shape of the drive electrode and other edges in the other direction are defined by the shape of the insulator. In such configuration, even if the plural light emitting elements are placed in line on the light emitting element array with a short pitch, the space between neighboring light emitting areas can be shorter, and the light emitting area can be obtained larger. Therefore, it is possible to realize the exposure with high picture quality and high resolution.

In accordance with still another aspect of the present invention, there is provided with an exposing apparatus with plural light emitting element, each light emitting element comprises a light emitting area having a lower electrode, an organic multilayer film with a light emitting layer and a counter electrode on a substrate, and an insulator formed by patterning on the substrate and placed between the lower electrode and the counter electrode, and covering ends of the lower electrode to prevent the light emitting from a covering area, wherein the light emitting area has a shape of which edges in a first direction (a specific direction) on the substrate are defined by at least the insulator and other edges in a second direction different from the first direction on the substrate are defined by at least one of the lower electrode formed by patterning on the substrate and the counter electrode by patterning on the substrate, and the plural light emitting elements are placed in line in the second direction so that the elements are electrically isolated each other.

In the above configuration, the light emitting area has a shape of which edges in the specific direction on the substrate are defined by the lower electrode and the other edges in the second direction (the main scanning direction) different from the specific direction are defined by the lower electrode or the counter electrode. In this configuration, since the edges of the light emitting area in the second direction, which are required the high accuracy, are defined by either the lower electrode or the counter electrode with the required accuracy, so that it is possible to ensure the required accuracy. Even if the plural light emitting elements are placed in line on the light emitting element array with a short pitch, the space between neighboring light emitting areas can be shorter, and the light emitting area can be obtained larger. Therefore, it is possible to realize the exposure with high picture quality and high resolution.

In the exposing apparatuses in the aspects, the organic multilayer film may be formed only on a gap between the neighboring insulators in the first direction. In this case, since the organic multilayer film is not formed on an unnecessary section, it is possible to reduce the necessary amount of the organic material and the cost. It is also possible to control the unevenness of the surface on the substrate on which the lower electrode, the insulator and the organic multilayer film are formed. It is possible to improve the reliability when the counter electrode is formed.

In the exposing apparatus, the edges of the light emitting area defined by the insulator and the other edges defined by the lower electrode or the counter electrode may be a straight line.

In the light emitting element configured as above, both the edges of the light emitting area defined by the insulator and the edges defined by the lower electrode or the counter electrode are a straight line, in case of the specific resolution, the shape of the light emitting area is a rectangle surrounded by the straight lines. Therefore, the size (area) of the light emitting area becomes the biggest, from which a large light volume can be obtained. It is possible to reduce the luminance, and extend the life of the light emitting element.

In the exposing apparatuses in the above aspects, the edges of the light emitting area defined by the insulator and the other edges defined by the lower electrode or the counter electrode may include a nonlinear part.

According to the above configuration, the edges of the light emitting area defined by the insulator and the edges defined by the lower electrode or the counter electrode include a nonlinear part, and the shape of the light emitting area can be optimized by forming in a shape including a circle or an ellipse based on the rectangle surrounded by straight lines, depending on a lens to be used and the exposing conditions.

In the exposing apparatuses in the above aspects, the insulator may be made of an inorganic material, such as SiNx, SiO₂, and the like.

According to the above configuration, the insulator is formed by organic material, such as SiNx, SiO₂, and the like. In result, it is possible to ensure the uniformity of the thickness of the light emitting layer, the unevenness of the light emitted from the light emitting area can be controlled, and the life of the light emitting element can be extended. By means of this light emitting element, it is possible to ensure the high picture quality, the high resolution, and the high reliability of the printer.

In the exposing apparatuses in the above aspects, the insulator may range in thickness from 100 nm to 3000 nm.

According to such configuration, the thickness of the insulator ranges from 100 nm to 300 nm, and the light emitting element can be optimized in order to ensure the insulating properties and obtain the uniformity of the film thickness of the light emitting area.

In the exposing apparatuses in the above aspects, the light emitting area may be placed so that the resolution becomes 600 dpi and more.

According to such configuration, the light emitting area is placed so that the resolution becomes 600 dpi and more, so that it is possible to realize the printer having high-resolution properties wherein kanji characters can be printed in high resolution.

The exposing apparatuses in the above aspects may comprises a thin film transistor that has a one-to-one correspondence with the light emitting element and is formed on the substrate for driving the light emitting element.

Regarding the electric drive system in the exposing apparatus configured as above, the thin film transistor is formed on the substrate so as to be a one-to-one correspondence with the light emitting element, and the thin film transistor drives each light emitting element directly. Therefore, the structure of the exposing apparatus can be simplified and it is possible to downsize apparatus to use the exposing apparatus. There is an advantage of the inexpensiveness.

In the exposing apparatuses in the above aspects, the thin film transistor may be made of amorphous silicon or polysilicon.

Where the thin film transistor is made of polysilicon having the high mobility of electrons, the electric capacity is increased, the speed of response is improved. It is possible to realize the high luminance and the high driving. It makes it easy to speed up the response to the printer and the digital multi-function printer.

In the exposing apparatuses in the above aspects, the organic multilayer film may be configured so as not to be formed on a whole area of the insulator. In this case, since the organic multilayer film is not formed on an unnecessary section, it is possible to reduce the necessary amount of the organic material and the cost. It is also possible to control the unevenness of the surface on the substrate on which the lower electrode, the insulator and the organic multilayer film are formed. It is possible to improve the reliability when the counter electrode is formed.

In the exposing apparatuses in the above aspects, the insulator may be made of a hydrophilic material. In this configuration, the insulator made of the hydrophilic material does not repel the organic multilayer film in a position surrounding the section to be the light emitting area, and the insulator is compatible with the organic multilayer film, so that the edges of the light emitting area can be formed accurately by the insulator formed by patterning. Since the thickness of the organic multilayer film can be formed uniformly especially at the boundary between the organic multilayer film and the insulator, it is possible to make the light volume distribution and the light angle distribution uniform.

In accordance with still another aspect of the present invention, there is provided with a method of manufacturing a light emitting element having a light emitting area with a lower, an organic multilayer film with a light emitting layer and a counter electrode on a substrate, comprising the steps of forming the lower electrode on the substrate, forming the insulator by patterning on the substrate with the lower electrode, forming the organic multilayer film including the light emitting layer on the substrate with the lower electrode and the insulator, and forming the counter electrode on the substrate on which the lower electrode, the insulator and the organic multilayer film, wherein, in at least one step of the step of forming the lower electrode and the step of forming the counter electrode, the lower electrode is formed by patterning on the substrate or the counter electrode is formed by patterning on the substrate, and the light emitting area has a shape of which edges are defined by the insulator, and other edges are defined by the lower electrode or the counter electrode.

In this configuration, depending on the required accuracy in a part of edge of the light emitting area, the part of edge is defined by any one of the lower electrode, the counter electrode or the dielectric film with the required accuracy, so that it is possible to ensure the required accuracy. Moreover, even if the plural light emitting elements are placed in line on the light emitting element array with a short pitch, the space between neighboring light emitting areas can be shorter, and the light emitting area can be obtained larger. Therefore, it is possible to realize the light emitting element to perform the exposure with high picture quality and high resolution.

In this method of manufacturing a light emitting element, the organic multilayer may be formed by ejecting a liquid including a constituent material onto the substrate using the inkjet method and the like. In this configuration, since the formation of the organic multilayer film on an unnecessary section can be eliminated in a simple manner, it is possible to reduce the necessary amount of the organic material and the cost. It is also possible to control the unevenness of the surface on the substrate on which the lower electrode, the insulator and the organic multilayer film are formed. It is possible to improve the reliability when the counter electrode is formed thereon.

In the above method of manufacturing a light emitting element, the organic multilayer is formed by ejecting the liquid two or more times onto a specific section, or repeating the one or more liquid ejecting onto a specific section at twice or more. Accordingly, since plural times of the ejecting are made onto one section, it is possible to apply the liquid smoothly and more uniformly.

In accordance with still another aspect of the present invention, there is provided with a method of manufacturing a light emitting element array of which light emitting elements are placed in line, the light emitting element having a light emitting area with a lower electrode, an organic multilayer film with a light emitting layer and a counter electrode on a substrate, the method comprising the steps of forming the lower electrode on the substrate, forming the insulator by patterning on the substrate with the lower electrode, forming the organic multilayer film including the light emitting layer on the substrate with the lower electrode and the insulator, and forming the counter electrode on the substrate with the lower electrode, the insulator and the organic multilayer film, wherein in at least one step of the step of forming the lower electrode and the step of forming the counter electrode, the lower electrode is formed by patterning on the substrate or the counter electrode is formed by patterning on the substrate, and the light emitting area has a shape of which edges are defined by the insulator, and other edges are defined by the lower electrode or the counter electrode.

In this configuration, depending on the required accuracy in a part of edge of the light emitting area, the part of edge is defined by any one of the lower electrode, the counter electrode or the dielectric film with the required accuracy, so that it is possible to ensure the required accuracy. Moreover, even if the plural light emitting elements are placed in line on the light emitting element array with a short pitch, the space between neighboring light emitting areas can be shorter, and the light emitting area can be obtained larger. Therefore, it is possible to realize the light emitting element array to perform the exposure with high picture quality and high resolution.

In this method of manufacturing a light emitting element array, the organic multilayer is formed by ejecting a liquid including a constituent material onto the substrate from one or more ejection nozzles, while sliding the nozzles along the line of the light emitting elements. In this configuration, since the formation of the organic multilayer film on an unnecessary section can be eliminated in a simple manner even if the formation area on the light emitting element array is larger, it is possible to reduce the necessary amount of the organic material and the cost. It is also possible to control the unevenness of the surface on the substrate on which the lower electrode, the insulator and the organic multilayer film are formed, and improve the reliability when the counter electrode is formed thereon.

In the method of manufacturing a light emitting element array in the above aspect, the organic multilayer is formed by iteration of a liquid ejecting and a nozzle sliding, the liquid ejecting of ejecting a specific amount of liquid including a composition material from the ejection nozzle, and the nozzle sliding of sliding the ejection nozzle in a specific length in the line direction of the nozzles. In this configuration, it is possible to apply the liquid even if the light emitting element array has large area that is coated the liquid.

In the methods of manufacturing a light emitting element array in the above aspects, the liquid is ejected from the ejection nozzle when the nozzle slides to one direction along the line of the light emitting elements. If it is necessary to improve the position accuracy of the ejected liquid for the section to be covered with the liquid, the ejecting is made only shifting the ejection nozzles in one direction along the line of the light emitting elements (one-path: one of the back and forth ways of the reciprocating motion along the line). It is possible to reduce the non-uniformity of the liquid ejected in the sub-scanning direction for every position.

In the methods of manufacturing a light emitting element array in the aspects, the liquid may be ejected from the ejection nozzle when the nozzle slides to both directions along the line of the light emitting elements. The ejecting is made sliding the ejection nozzles in both directions along the line of the light emitting elements (two-path: both ways of the reciprocating motion along the line). It is possible to apply the liquid on the specific section to be covered with the liquid in a very short time.

In the methods of manufacturing the light emitting element array in the aspects, the organic multilayer film may be formed by a set of liquid ejectings from a group of ejection nozzles that are placed in the line as long as the line of the light emitting areas. In this configuration, in case of the light emitting element array of which the sections to be covered with the liquid is large, the organic multilayer film is not formed on the unnecessary section, therefore the necessary amount of the organic material can be reduced, and it is possible to reduce the cost. In addition, it is also possible to control the unevenness of the surface on the substrate on which the lower electrode, the insulator and the organic multilayer film are formed, and improve the reliability when the counter electrode is formed thereon. And the applying of the liquid can be made in a short time in a simple manner, and the manufacturing cost can be reduced.

In the methods of manufacturing light emitting element array in the aspects, the organic multilayer film may be formed by a set of liquid ejectings from a group of ejection nozzles that are placed in the line as long as the line of the light emitting elements. In this configuration, the organic multilayer film can be formed by applying the liquid thinly without shifting the ejection nozzles or the substrate. Accordingly, in case of the light emitting element array of which the sections to be covered with the liquid is large, the organic multilayer film is not formed on the unnecessary section by a set of liquid ejectings of the group of nozzles, and the necessary amount of the organic material can be reduced, and it is possible to reduce the cost. In addition, it is also possible to control the unevenness of the surface on the substrate on which the lower electrode, the insulator and the organic multilayer film are formed, and improve the reliability when the counter electrode is formed thereon. And the applying of the liquid can be made in a short time in a simple manner, and the manufacturing cost can be reduced.

In the methods of manufacturing the light emitting element array in the aspects, the organic multilayer film may be formed by ejecting the liquid two or more times onto a specific section, or repeating the one or more liquid ejecting onto a specific section at twice or more. In this configuration, since the ejecting onto one section can be made plural times, the liquid can be applied smoothly and uniformly.

### INDUSTRIAL APPLICABILITY

The light emitting element in the invention can realize the exposing apparatus with high resolution, of which main scanning direction is 1200 dpi or 2400 dpi, with keeping the required size of the light emitting element. If the circuit scale of the thin film transistor forming the active matrix drive circuit gets large in order to control the light volume with high accuracy, if it is driven with a large current in order to increase the luminance, that is, when the size of the transistor gets large, it is possible to ensure a space for the TFT in the sub-scanning direction. In result, the invention can be applied to the exposure head mounted to the printer, the copying machine, the facsimile machine, and on-demand-type printer; those employing the electrophotographic system using the powder or liquid toner.

1. A light emitting element comprising:
a drive electrode on which voltage for the light emitting is applied;
an insulator that covers ends of the drive electrode; and
a light emitting area defined by the drive electrode and the insulator.

2. A light emitting element according to claim 1, wherein a shape of the light emitting area is defined by a shape of the drive electrode and a shape of the insulator.

3. A light emitting element array having plural light emitting elements placed in line, the light emitting element according to claim 2, wherein
the light emitting area has a shape of which edges in the line direction are defined by the shape of the drive electrode and other edges in the other direction are defined by the shape of the insulator.

4. A light emitting element having a light emitting area including a lower electrode, an organic multilayer film with a light emitting layer and a counter electrode on a substrates comprising:
an insulator formed by patterning on the substrate and placed between the lower electrode and the counter electrode, and covering ends of the lower electrode to prevent the light emitting from a covering area; and
a light emitting area having a shape of which edges are defined by the insulator and other edges are defined by the lower electrode formed by patterning on the substrate or the counter electrode formed by patterning on the substrate.

5. A light emitting element having a light emitting area including a lower electrode, an organic multilayer film with a light emitting layer and a counter electrode on a substrate, comprising:
an insulator formed by patterning on the substrate and placed between the lower electrode and the counter electrode, and covering ends of the lower electrode to prevent the light emitting from a covering area; and
a light emitting area having a shape of which edges in a first direction on the substrate are defined by at least the insulator, and other edges in a second direction different from the first direction on the substrate are defined by at least one of the lower electrode formed by patterning on the substrate and the counter electrode formed by patterning on the substrate.

6. A light emitting element according to claim 5, wherein the second direction is approximately perpendicular to the first direction.

7. A light emitting element according to claim 4, wherein the edges of the light emitting area defined by the insulator and the other edges defined by the lower electrode or the counter electrode are a straight line.

8. A light emitting element according to claim 4, wherein the edges of the light emitting area defined by the insulator and the other edges defined by the lower electrode or the counter electrode include a nonlinear part.

9. A light emitting element according to claim 4, wherein the insulator is made of an inorganic material.

10. A light emitting element according to claim 4, wherein the insulator ranges in thickness from 100 nm to 3000 nm.

11. A light emitting element according to claim 5, wherein the organic multilayer film is formed without covering all over the insulator.

12. A light emitting element according to claim 1, wherein the insulator is made of a hydrophilic material.

13. A light emitting element according to claim 5, wherein the organic multilayer film is formed between the neighboring insulators in the first direction.

14. An exposing apparatus including light emitting elements, each light emitting element comprising:
a drive electrode on which voltage for the light emitting element is applied;
an insulator for covering ends of the drive electrode; and
a light emitting area defined by the drive electrode and the insulator.

15. An exposing apparatus according to claim 14, wherein a shape of the light emitting area is defined by a shape of the drive electrode and a shape of the insulator.

16. An exposing apparatus according to claim 15, of which light emitting elements are placed in line, wherein
the shape of the light emitting area is a shape of which edges in the line direction are defined by the shape of the drive electrode and other edges in the other direction are defined by the shape of the insulator.

17. An exposing apparatus with plural light emitting elements, each light emitting element comprising:
a light emitting area having a lower electrode, an organic multilayer film with a light emitting layer and a counter electrode on a substrate; and
an insulator formed by patterning on the substrate and placed between the lower electrode and the counter electrode, and covering ends of the lower electrode to prevent the light emitting from a covering area; and
wherein the light emitting area has a shape of which edges in a first direction on the substrate are defined by at least the insulator, and other edges in a second direction different from the first direction on the substrate are defined by at least one of the lower electrode formed by patterning on the substrate and the counter electrode formed by patterning on the substrate, and the plural light emitting elements are placed in line in the second direction so that the elements are electrically isolated each other.

18. An exposing apparatus according to claim 17, wherein the edges of the light emitting area defined by the insulator and the other edges defined by the lower electrode or the counter electrode are a straight line.

19. An exposing apparatus according to claim 17, wherein the edges of the light emitting area defined by the insulator and the other edges defined by the lower electrode or the counter electrode include a nonlinear part.

20. An exposing apparatus according to claim 17, wherein the insulator is made of an inorganic material.

21. An exposing apparatus according to claim 17, wherein the insulator ranges in thickness from 100 nm to 3000 nm.

22. An exposing apparatus according to claim 17, wherein the light emitting area is placed so that the resolution becomes 600 dpi and more.

23. An exposing apparatus according to claim 17, further comprising:
a thin film transistor that has a one-to-one correspondence with the light emitting element and is formed on the substrate for driving the light emitting element.

24. An exposing apparatus according to claim 23, wherein the thin film transistor is made of amorphous silicon or polysilicon.

25. An exposing apparatus according to claim 17, wherein the organic multilayer film is formed without covering all over the insulator.

26. An exposing apparatus according to claim 14, wherein the insulator is made of a hydrophilic material.

27. An exposing apparatus according to claim 17, wherein the organic multilayer film is formed only between the insulators neighboring in the first direction.

28. A method of manufacturing a light emitting element having a light emitting area with a lower electrode, an organic multilayer film with a light emitting layer and a counter electrode on a substrate, comprising:
forming the lower electrode on the substrate;
forming the insulator formed by patterning on the substrate with the lower electrode;
forming the organic multilayer film including the light emitting layer on the substrate with the lower electrode and the insulator; and
forming the counter electrode on the substrate on which the lower electrode, the insulator and the organic multilayer film are formed; and wherein
in at least one of the forming the lower electrode and the forming the counter electrode, the lower electrode is formed by patterning on the substrate or the counter electrode is formed by patterning on the substrate, and
the light emitting area has a shape of which edges are defined by the insulator, and other edges are defined by the lower electrode or the counter electrode.

29. A method of manufacturing a light emitting element according to claim 28, wherein the organic multilayer film is formed by ejecting a liquid including a constituent material onto the substrate.

30. A method of manufacturing a light emitting element according to claim 29, wherein the organic multilayer film is formed by ejecting the liquid two or more times onto a specific section at a time, or by applying twice or more a set of the one liquid ejecting or twice or more liquid ejectings onto a specific section at intervals over time.

31. A method of manufacturing a light emitting element array of which light emitting elements are placed in line, the light emitting element having a light emitting area with a lower electrode, an organic multilayer film with a light emitting layer and a counter electrode on a substrate, the method comprising:
forming the lower electrode on the substrate;
forming the insulator formed by patterning on the substrate with the lower electrode;
forming the organic multilayer film including the light emitting layer on the substrate with the lower electrode and the insulator; and
forming the counter electrode on the substrate with the lower electrode, the insulator and the organic multilayer film; and wherein
in at least one of the forming the lower electrode and the forming the counter electrode, the lower electrode is formed by patterning on the substrate or the counter electrode is formed by patterning on the substrate, and
the light emitting area has a shape of which edges are defined by the insulator, and other edges are defined by the lower electrode or the counter electrode.

32. A method of manufacturing a light emitting element array according to claim 31, wherein the organic multilayer film is formed by ejecting a liquid including a constituent material onto the substrate from one or more ejection nozzles, while sliding the nozzles along the line of the light emitting elements.

33. A method of manufacturing a light emitting element array according to claim 32, wherein the organic multilayer film is formed by iteration of a liquid ejecting and a nozzle sliding, the liquid ejecting of ejecting a specific amount of the liquid from the ejection nozzles and the nozzle sliding of sliding the ejection nozzles in a specific length in the line direction of the nozzles.

34. A method of manufacturing a light emitting element array according to claim 32, wherein the liquid is ejected from the ejection nozzle when the nozzle slides to one direction along the line of the light emitting elements.

35. A method of manufacturing a light emitting element array according to claim 32, wherein the liquid is ejected from the ejection nozzle when the nozzle slides to both directions along the line of the light emitting elements.

36. A method of manufacturing a light emitting element array according to claim 31, wherein the organic multilayer film is formed by a set of liquid ejectings from a group of ejection nozzles that arc placed in the line as long as the line of the light emitting areas.

37. A method of manufacturing a light emitting element array according to claim 31, wherein the organic multilayer film is formed by a set of liquid ejectings from a group of ejection nozzles that are placed in the line as long as the line of the light emitting elements.

38. A method of manufacturing a light emitting element array according to claim 32, wherein the organic multilayer film is formed by ejecting the liquid two or more times onto a specific section at a time, or by applying twice or more a set of the one liquid ejecting or twice or more liquid ejectings onto a specific section at intervals over time.
